(19) United States
(12) Patent Application Publication
(10) Pub. No.: US 2026/0173418 A1
(43) Pub. Date: Jun. 18, 2026

(54) METHOD FOR MANUFACTURING AN ELECTRONIC DEVICE

(71) Applicant: STMicroelectronics International N.V., Geneva (CH)

(72) Inventor: Pascal CHEVALIER, Chapareillan (FR)

(73) Assignee: STMicroelectronics International N.V., Geneva (CH)

(21) Appl. No.: 19/421,626

(22) Filed: Dec. 16, 2025

(30) Foreign Application Priority Data
Dec. 18, 2024 (FR) FR2414424

(51) Int. Cl. H10D 10/01; H10D 10/40

(52) U.S. Cl. CPC H10D 10/051; H10D 10/40

(57) ABSTRACT

An electronic device includes a bipolar transistor having: a collector; an emitter; an intrinsic base made of a monocrystalline semiconductor material, where the intrinsic base rests on the collector and the emitter rests on the intrinsic base; an extrinsic base including a first portion made of a monocrystalline semiconductor material and a second portion made of polycrystalline semiconductor material; and a first layer. In making the device, the first portion is formed from the intrinsic base and the second portion is formed from the first layer.

### PRIORITY CLAIM

This application claims the priority benefit of French Application for Patent No. FR2414424, filed on Dec. 18, 2024, the content of which is hereby incorporated by reference in its entirety to the maximum extent allowable by law.

### TECHNICAL FIELD

The present disclosure generally concerns electronic devices and their manufacturing methods and, more specifically, devices comprising a bipolar transistor and their manufacturing methods.

### BACKGROUND

A bipolar transistor is a semiconductor-based electronic device of the family of transistors. Its operating principle is based on two PN junctions, one forward and one reverse.

Bipolar transistor manufacturing methods comprise, for example, steps of forming of an extrinsic base. Such steps may be a problem.

### SUMMARY

In an embodiment, a method of manufacturing an electronic device comprising a bipolar transistor, where the bipolar transistor comprises: a collector region; an emitter region; an intrinsic base region, the intrinsic base region being made of a monocrystalline semiconductor material, the intrinsic base region resting on an upper surface of the collector region and the emitter region resting on an upper surface of the intrinsic base region; an extrinsic base region, the extrinsic base region comprising a first portion made of a monocrystalline semiconductor material and a second portion made of a polycrystalline semiconductor material; and a first layer made of a material on which it is possible to grow the material of the second portion by epitaxy; the method comprising steps: a) forming the first portion by epitaxial growth from the upper surface of the intrinsic base region; and b) forming the second portion by epitaxial growth from the upper surface of the first layer.

Another embodiment provides an electronic device comprising a bipolar transistor, the bipolar transistor comprising: a collector region; an emitter region; an intrinsic base region, the intrinsic base region being made of a monocrystalline semiconductor material, the intrinsic base region resting on an upper surface of the collector region and the emitter region resting on an upper surface of the intrinsic base region; an extrinsic base region, the extrinsic base region comprising a first portion made of a monocrystalline semiconductor material and a second portion made of a polycrystalline semiconductor material; and a first layer made of a material on which it is possible to grow the material of the second portion by epitaxy, the first portion resting on the upper surface of the intrinsic base region and the second portion resting on the first layer.

According to an embodiment, the transistor comprises a second layer made of a silicide-type material at least partially covering the first portion and at least partially covering the second portion.

According to an embodiment, the second layer is in contact with the first portion.

According to an embodiment, the intrinsic base region is in contact with the collector region and with the emitter region.

According to an embodiment, the first layer is separated from the intrinsic base region by a portion of insulating material.

According to an embodiment, the transistor comprises a spacer extending above the intrinsic base region, surrounding the interface area between the emitter region and the intrinsic base region.

According to an embodiment, the method comprises, prior to steps a) and b): c) forming the collector region in a support; d) forming a stack of insulating layers in which the first layer is located; e) forming in the stack of insulating layers a first cavity running through the stack of insulating layers and a second cavity at the location of the intrinsic base region; f) forming the intrinsic base in the second cavity; and g) forming the spacer along the walls of the first cavity.

According to an embodiment, the method comprises, before steps a) and b) and after step g): h) forming the emitter region; i) encapsulating the emitter region; and j) etching the layers of the stack of insulating layers so as to at least partially expose the first layer and the upper surface of the intrinsic base region.

According to an embodiment, the spacer is made of polysilicon. An advantage of having the spacer made of polysilicon is a reduction of the resistance of the emitter and improves the reliability of the device.

According to an embodiment, the spacer is made of silicon nitride.

According to an embodiment, the method comprises, after steps a) and b), forming the second layer at least partially on the first portion and at least partially on the second portion.

According to an embodiment, steps a) and b) are simultaneously carried out.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows an embodiment of an electronic device comprising a bipolar transistor;

FIGS. 2A to 2G show structures resulting from steps of a method of manufacturing the device of FIG. 1; and

FIGS. 3A to 3D show structures resulting from steps of another method of manufacturing a device comprising a bipolar transistor according to another embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only those steps and elements that are useful for understanding the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as the terms “front”, “back”, “top”, “bottom”, “left”, “right”, etc., or relative position qualifiers, such as the terms “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10% or 10°, preferably of plus or minus 5% or 5°.

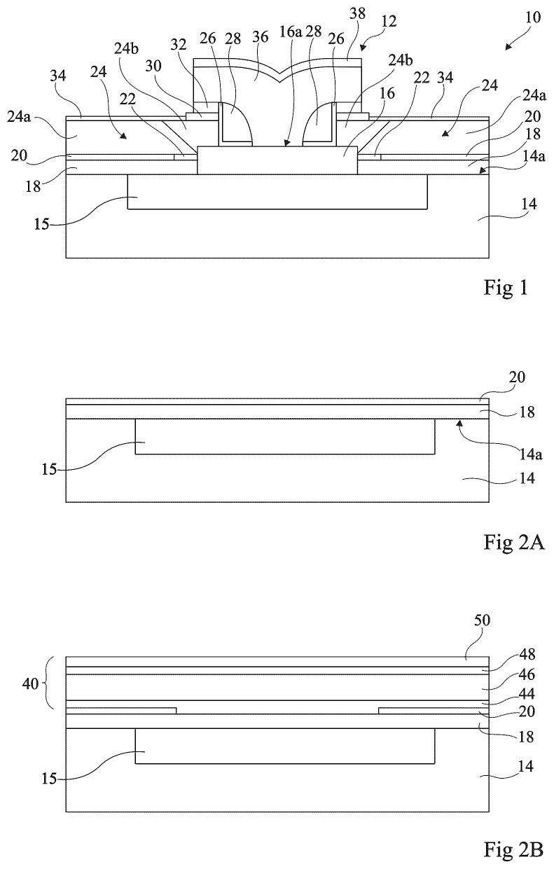

FIG. 1 shows an example of an electronic device 10 comprising a bipolar transistor 12.

Device 10 comprises a support 14, for example a semiconductor substrate, for example made of silicon. Transistor 12 is formed inside and on top of support 14. Support 14 comprises, in particular, a doped region, not shown, forming the collector 15 of bipolar transistor 12. Said doped region is doped with a first conductivity type, N or P.

Transistor 12 further comprises an intrinsic base region 16. Region 16 is located on, preferably in contact with, an upper surface 14a of support 14. Region 16 is preferably in contact with the collector region, not shown. Region 16 is made of a doped semiconductor material of a second conductivity type, opposite to the first conductivity type. Region 16 is made of a monocrystalline material. For example, region 16 is made of silicon, for example made of epitaxial silicon. Region 16 is, for example, made of SiGe, for example made of epitaxial SiGe. Region 16 has, for example, a variable dopant concentration. For example, there exists a dopant concentration gradient in region 16.

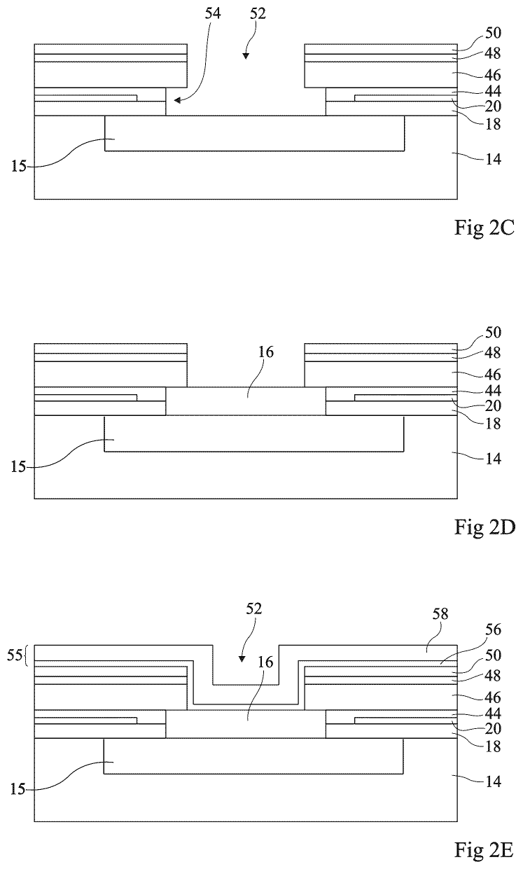

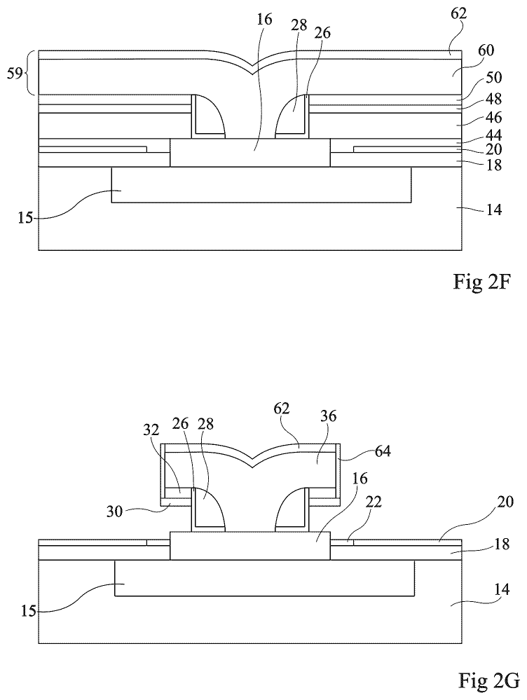

Region 16 has, for example, a cuboid shape. Region 16 comprises a lower surface, preferably in contact with the collector region of support 14. Region 16 comprises an upper surface, opposite to the lower surface and preferably substantially parallel to the lower surface of region 16. Region 16 further comprises lateral surfaces, coupling the upper and lower surfaces. In the illustrated example, region 16 extends on a portion only of the upper surface 14a of support 14. For example, region 16 extends on a central portion only of the upper surface 14a of support 14. For example, region 16 extends in a central portion only of the upper face of the collector region 15. Intrinsic base region 16 is for example formed by selective epitaxy as described later in relation with FIG. 2C.

Device 10 further comprises an insulating layer 18. Layer 18 is made of a first insulating material, preferably made of silicon oxide. Layer 18 surrounds region 16. Layer 18 covers the upper surface 14a of support 14. Layer 18 is preferably in contact with the upper surface 14a of support 14. In the illustrated example, layer 18 covers a peripheral portion of the upper surface of the collector region 15. Layer 18 is in lateral contact with region 16, that is, in contact with the lateral surfaces of region 16. More precisely, a lower portion of region 16, and thus a lower portion of the lateral surfaces of region 16, is surrounded by, and in contact with, layer 18. By lower portion of region 16, there is meant the portion closest to support 14.

Device 10 comprises a layer 20. Layer 20 is made of a material allowing the epitaxial growth of a semiconductor material. Preferably, layer 20 is made of a material enabling a semiconductor material to non-selectively grow on said layer 20, for example during a selective epitaxial growth step. Layer 20 is, for example, made of one of amorphous silicon, polysilicon, or silicon nitride.

Layer 20 rests on, and is preferably in contact with, layer 18. Layer 20 surrounds region 16, more precisely surrounds an intermediate portion of region 16, and thus an intermediate portion of the lateral surfaces of region 16. The intermediate portion of region 16 is separated from support 14 by the lower portion of region 16.

Layer 20 is separated from region 16 by a layer 22. Layer 22 is made of an insulating material. Layer 22 is, for example, made of the same material as layer 18, for example made of the first material, for example made of silicon oxide.

Bipolar transistor 12 comprises an extrinsic base region 24. Region 24 surrounds region 16, and more precisely surrounds an upper portion of intrinsic base region 16, and thus an upper portion of the lateral surfaces of region 16. The upper portion of region 16 is the portion of region 16 most distant from support 14. Region 24 also covers a peripheral portion of the upper surface of region 16. The thickness of region 24 is thus greater than the thickness of the upper portion of region 16.

Region 24 comprises a portion 24a. Portion 24a is made of polycrystalline semiconductor material. Portion 24a is made of a doped material of the same conductivity type as that of region 16. Portion 24a is, for example, made of silicon, for example made of epitaxial silicon. Portion 24a is made, for example, of SiGe, for example made of epitaxial SiGe. Portion 24a covers, for example entirely, layer 20. Portion 24a is preferably in contact with the upper surface of layer 20. Portion 24a covers, for example at least partially, layer 28. Portion 24a is preferably in contact with at least part of the upper surface of layer 22.

Region 24 comprises a portion 24b. Portion 24b is made of a monocrystalline semiconductor material. Portion 24b is made of a doped material of the same conductivity type as that of region 16. Portion 24b is, for example, made of silicon, for example made of epitaxial silicon. Portion 24b is, for example, made of SiGe, for example made of epitaxial SiGe. Portion 24b partially covers the upper surface of region 16, more precisely covers the peripheral portion of the upper surface of layer 16. Portion 24b is preferably in contact with said peripheral portion of the upper surface of layer 16. In the example of FIG. 1, portion 24b further covers, and is preferably in contact with, an upper portion of the lateral surfaces of region 16. As a variant, the upper portion of the lateral surfaces of region 16 is covered by portion 24a.

Portion 24b is, for example, uniformly doped. Portion 24b is also more heavily doped than region 16, preferably at least ten times more heavily doped.

Extrinsic base region 24 thus comprises a polycrystalline portion 24a and a monocrystalline portion 24b. The monocrystalline portion 24b of the extrinsic base region 24 is in vertical contact with the intrinsic base region 16. The monocrystalline portion 24b of the extrinsic base region is thus not in exclusively lateral contact with the intrinsic base region 16.

For example, the greater the distance from support 14, the greater the width of portion 24b. By width of portion 24b, it is meant the distance between the lateral surface of region 24 closest to region 16 and the opposite lateral surface of portion 24b. In other words, the portion of portion 24a closest to region 16 is located between portion 24b and support 14. The remainder of portion 24a is not located between portion 24b and support 14.

Bipolar transistor 12 further comprises a layer 26 comprising a horizontal portion extending over part of the upper surface of region 16 and a vertical portion extending over the lateral surface of portion 24b closest to region 26. A central portion 16a of the upper surface of region 16 is not covered by layer 26. Layer 26 is covered by a spacer 28. Spacer 28 does not cover said central portion 16a.

Layer 26 is, for example, made of the same material as layers 18 and 22. Spacer 28 is made of the same material as layer 20, but preferably with a different doping. Preferably, spacer 28 is made of amorphous silicon.

Portion 24b is partially covered by insulating layers 30 and 32. The portion of portion 24b closest to layer 26 is covered by insulating layers 30 and 32. Layer 30 is located in contact with portion 24b. Layer 32 at least partially covers layer 30. The lateral surfaces of layers 30 and 32 closest to layer 26 are preferably covered by layer 26. Layer 30 is, for example, made of the same material as layer 26, for example made of silicon oxide. Layer 30 is preferably made of an insulating material different from the material of layer 32. For example, layer 32 is made of silicon nitride. A portion of the upper surface of portion 24b is not covered by layers 30 and 32. Preferably, the portion of the upper surface of portion 24b most distant from layer 26 is not covered by layers 30 and 32.

Device 10 comprises a layer 34 at least partially covering portion 24a and at least partially covering portion 24b. Preferably, the entire part of the upper surface of portion 24b not covered by layer 30 is covered by layer 34. Layer 34 is, for example, made of a low-resistivity material, for example made of a metal silicide, for example titanium silicide (TiSi), cobalt silicide (CoSi2), or nickel silicide (NiSi).

Transistor 12 comprises an emitter region 36. Region 36 is made of a semiconductor material, for example made of silicon, for example made of epitaxial silicon. Region 36 is preferably doped with the same conductivity type as the collector region, not shown. Region 36 is, for example, made of a polycrystalline material. Region 36 is, for example, made of epitaxial polysilicon or monocrystalline silicon doped with arsenic or phosphorus.

Region 36 covers the central portion of region 16 and is thus in contact with region 16. Region 36 further covers spacer 28, layer 26, and layer 32. Region 36 does not cover, and is not in contact with, layer 34 or region 24.

The upper surface of region 36 is covered by a layer 38. Layer 38 is made, for example, of the same material as layer 34.

Device 10 further comprises contact pads configured to deliver bias voltages to the collector, to the base, and to the emitter. One contact pad is thus, for example, in contact with layer 38 so as to bias the emitter. Another contact pad is, for example, in contact with layer 34 so as to bias the base. Another contact pad is, for example, in contact with the support so as to bias the collector.

With region 16 and portion 24b being made of monocrystalline materials, the interface between the intrinsic base and the extrinsic base does not lead to a significant increase in the base resistance, as opposed to an interface between polycrystalline and monocrystalline materials. With layer 34 covering portions 24a and 24b, the electrical connection between the base contact pad and portion 24b is not significantly disrupted by the interface between portions 24a and 24b.

In device 10, layer 20 from which portion 24a of extrinsic base 24 is grown is a planar layer extending above the upper surface 14a of semiconductor support 14. Said differently, layer 20 from which portion 24a of extrinsic base 24 is grown is not buried in semiconductor support 14. An advantage of this configuration is that it avoids or limits parasitical capacitance between the extrinsic base 24 and the semiconductor support 14, and more particularly between the extrinsic base 24 and the collector region 15.

FIGS. 2A to 2G show structures resulting from steps, preferably successive, of a method of manufacturing the device of FIG. 1.

FIG. 2A shows a structure resulting from a step of a method of manufacturing the device of FIG. 1.

During this step, collector region 15 is formed in support 14.

During this step, insulating layer 18 is formed on support 14. During this step, layer 18 preferably entirely covers the upper surface 14a of layer 14.

The step of FIG. 2A further comprises forming layer 20. Layer 20 covers layer 18. During this step, layer 20 preferably entirely covers the upper surface of layer 18. Layer 20 is thus entirely separated from substrate 14 by layer 18.

FIG. 2B shows a structure resulting from a step of a method of manufacturing the device of FIG. 1.

During this step, layer 20 is etched. More specifically, the portions of layer 20 located at the positions of layer 22 and of region 16 are removed. Preferably, only the portions of layer 20 still present in the structure of FIG. 1 are preserved during the etching step of FIG. 2B. In the shown example, layer 20 is removed only opposite a central portion of the collector region 15, and is preserved opposite a peripheral portion of the collector region 15.

The step of FIG. 2B further comprises forming, preferably over the entire structure, on the upper surface of the structure, a stack 40 of insulating layers 44, 46, 48, and 50.

Layer 44 covers, and is preferably in contact with, layer 20 and the portion of layer 18 exposed by the step of etching of layer 20. Layer 46 covers, and is preferably in contact with, layer 44. Layer 48 covers, and is preferably in contact with, layer 46. Layer 50 covers, and is preferably in contact with, layer 48.

Layer 44 is made of the material of the layer 22 of FIG. 1. Preferably, layer 44 is made of the same material as layer 18, for example made of silicon oxide. Layer 48 is made of the material of the layer 30 of FIG. 1. Layer 48 is preferably made of the same material as layer 44, for example made of silicon oxide. Layer 46 is, for example, made of silicon nitride. Layer 50 is made of the material of layer 32. Layer 50 is preferably made of the same material as layer 46. The material of layers 44 and 48 and the material of layers 46 and 50 are preferably selectively etchable with respect to each other.

FIG. 2C shows a structure resulting from a step of a method of manufacturing the device of FIG. 1.

The step of FIG. 2C comprises a step of etching of a cavity 52. The cavity runs through layers 18, 44, 46, 48, and 50. Cavity 52 preferably does not extend into support 14. Similarly, cavity 52 does not extend into layer 20. Cavity 52 thus runs through layer 44 at a location where layer 20 has been etched. More specifically, cavity 52, which corresponds to the emitter window, is located at the position of layer 26, of spacer 28, and of region 36.

The step of FIG. 2C further comprises a step of deoxidation of layers 18 and 44. Thus, a laterally extending cavity 54 is formed in layers 18 and 44 so as to remove layers 18 and 44 from the locations of region 16. In the shown example, cavity 54 extends only above a central portion of the upper surface of collector region 15.

FIG. 2D shows a structure resulting from a step of a method of manufacturing the device of FIG. 1.

During this step, region 16 is formed. More precisely, region 16 is formed at the location of the etched portion of layers 18 and 44. Thus, region 16 is formed in lateral cavity 54 and in the lower portion of cavity 52, in such a way that the upper surface of region 16 is coplanar with the upper surface of layer 44. Region 16 is, for example, formed by epitaxy. Region 16 is, for example, formed by selective epitaxy.

FIG. 2E shows a structure resulting from a step of a method of manufacturing the device of FIG. 1.

During this step, a stack 55 of layers 56 and 58 is formed conformally on the structure resulting from the step of FIG. 2D. Layer 56 is made of the material of layer 26, for example made of an insulating material, for example made of silicon oxide. Layer 58 is made of the material of spacer 28. The material of layer 56 is different from the material of layer 58. The thicknesses of layers 56 and 58 are selected so that layers 56 and 58 do not fill cavity 52.

FIG. 2F shows a structure resulting from a step of a method of manufacturing the device of FIG. 1.

During this step, layer 58 is anisotropically etched. Spacer 28 is thus formed from layer 58. Portions of layer 56 not covered by spacer 28 are then etched so as to form layer 26.

During this step, a stack 59 of layers 60 and 62 is formed conformally on the structure resulting from the step of FIG. 2E. In particular, stack 59 rests on layer 50, layer 26, spacer 28, and region 16. Layer 60 is made of the material of region 36 so as to form the emitter region. Layer 62 is made of a passivating material, for example made of the same material as layer 48, for example made of silicon oxide.

FIG. 2G shows a structure resulting from a step of a method of manufacturing the device of FIG. 1.

The step of FIG. 2G comprises a step of etching of layers 50, 60, and 62. The etching is, for example, an anisotropic etching. Layers 50 and 60 are etched so as to form region 36 and layer 32. Layer 62 is etched along a same plane. Thus, the layer 62 resulting from the etch step of FIG. 2G entirely covers the upper surface of region 36, preferably only the upper surface of region 36.

The step of FIG. 2G further comprises the forming of an encapsulation layer 64. Layer 64 is, for example, made of the same material as layer 38. Layer 64 covers the side walls of layers 50, 60, and 62.

The step of FIG. 2G further comprises the etching of the portions of layer 48 not covered by layers 32 and 64. Layer 48 is thus etched so as to form layer 30. The emitter region is thus encapsulated by layers 26, 30, 62, 64.

The step of FIG. 2G further comprises the etching of layer 46. Layer 46 is preferably entirely removed. In particular, the portion of layer 46 located between layer 30 and support 14, that is, beneath layer 30, is removed. Part of intrinsic base region 16 is thus exposed.

The step of FIG. 2G further comprises the etching of layer 44 so as to form layer 22. More precisely, layer 44 is etched until layer 20 is exposed. Thus, the portion of layer 44 located at the same level as layer 20, that is, located between layer 20 and region 16, is not etched. The layer 22 remaining after the etching has a surface coplanar with the upper surface of layer 20.

The method further comprises steps subsequent to the steps of FIG. 2G.

The method thus comprises the forming of extrinsic base region 24. The forming of region 24 is carried out by selective epitaxy. Thus, region 24 grows, by epitaxy, from the portion of region 16 exposed by the removal of layer 46 and from layer 20.

The epitaxial growth from region 16 enables to form portion 24b. The growth of portion 24b is carried out from the upper surface of region 16. Thus, the contact between region 16 and portion 24b is a vertical contact. Portion 24b, like region 26, is made of a monocrystalline semiconductor material.

Similarly, the epitaxial growth from layer 20 enables to form portion 24a. The growth of portion 24a is carried out from the upper surface of layer 20. Thus, the contact between layer 20 and portion 24a is a vertical contact. Portion 24a, like layer 20, is made of a polycrystalline semiconductor material.

The simultaneous growth of portions 24a and 24b provides the shape of the interface between portions 24a and 24b as shown in FIG. 1. More specifically, the simultaneous growth ensures that portion 24b extends further away from layer 26 at the upper surface of region 24 than at the lower surface of region 24. Part of the upper surface of portion 24a is thus exposed and is covered neither by layer 30 nor by portion 24a.

The method comprises the removal of layer 62. The method further comprises the forming of layer 38 and of layer 34. Layers 38 and 34 are, for example, made of the same material. Layers 38 and 34 are, for example, formed simultaneously by the forming of a same layer. Layer 38 thus covers the upper surface of region 36. Layer 34 covers portion 24a and at least partially portion 24b.

The method comprises, for example, an additional step of forming of spacers, not shown, on the side walls of layers 32 and 38 and of region 36.

During the steps of the device manufacturing method, the structure is heated, for example during anneal steps. During these anneal steps, the dopants of layer 60, and subsequently of region 36, are diffused into spacers 28. Thus, spacers 28 become, along the manufacturing method, part of region 36.

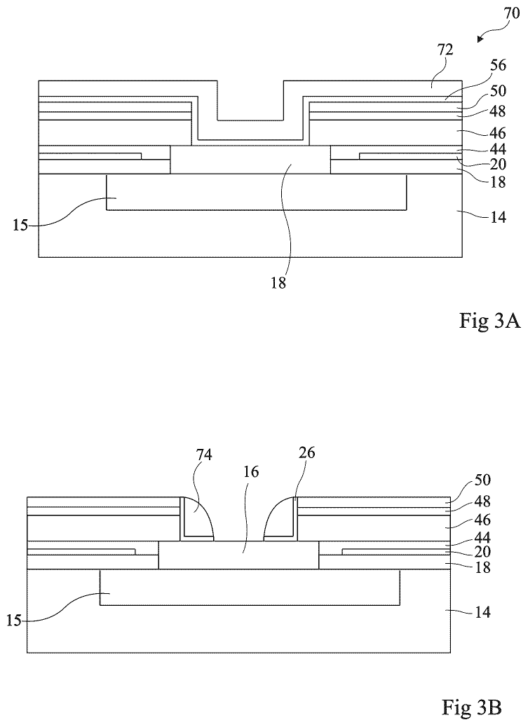

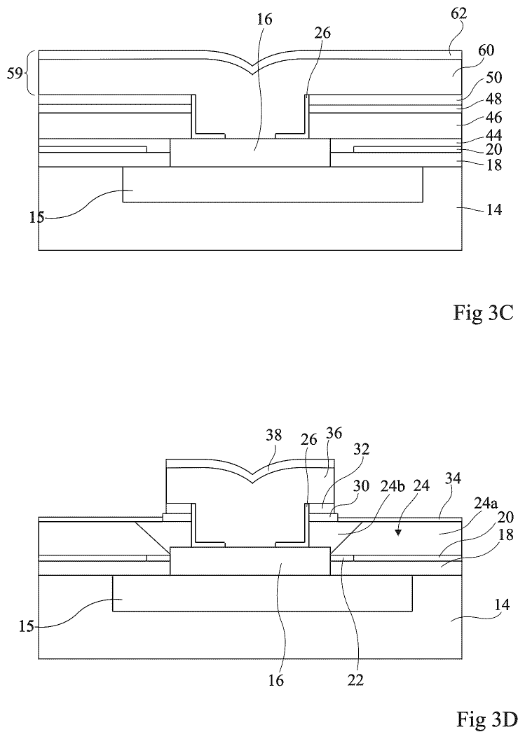

FIGS. 3A to 3D show structures resulting from steps, preferably successive, of another method of manufacturing a device 70 comprising a bipolar transistor according to another embodiment. More specifically, FIGS. 3A to 3D show structures resulting from steps of a method of manufacturing a device comprising a bipolar transistor differing from transistor 12 in that the transistor of device 70 does not comprise spacers 28.

The method of manufacturing device 70 comprises the steps of FIGS. 2A to 2D such as previously described.

FIG. 3A shows a structure resulting from a step of the method of manufacturing device 70, performed following the step of FIG. 2D.

The step of FIG. 3A differs from the step of FIG. 2E in that layer 58 is replaced by a layer 72 made of a material capable of being selectively etched over the material of layer 26, for example made of silicon nitride. Layer 72 is preferably identical to layer 58 except for the difference in material.

FIG. 3B shows a structure resulting from a step of the method of manufacturing device 70.

During the step of FIG. 3B, layer 72 is anisotropically etched. A spacer 74 is thus formed from layer 72. Spacer 74 is located at the position of the spacer 28 of device 10. Spacer 74 differs from spacer 28 in that spacer 74 is made of silicon nitride.

FIG. 3C shows a structure resulting from a step of the method of manufacturing device 70. The structure of FIG. 3C results from the same steps as the structure of FIG. 2F. More specifically, the stack 59 of layers 60 and 62 is conformally formed on the structure resulting from the step of FIG. 3B. In particular, stack 59 rests on layer 50, layer 26, and region 16. Layer 60 is made of the material of region 36 so as to form the emitter region. Layer 62 is made of a passivation material, for example made of the same material as layer 48, for example made of silicon oxide.

FIG. 3D shows a structure resulting from a step of the method of manufacturing device 70. During this step, the method comprises the removal, for example by etching, of spacers 74. The method then comprises the steps described in relation with FIGS. 2G and 2H.

An advantage of the described embodiments is that they enable to decrease the base resistance of the bipolar transistor. Indeed, the forming of an electrical connection between the base contact pad and the intrinsic base by layer 34 and portion 24b avoids the forming of an electrical connection running through an interface between a monocrystalline semiconductor material and a polycrystalline semiconductor material.

Another advantage of the described embodiments is that they enable to fill the transmitter cavity with a single material.

An advantage of the embodiment of FIGS. 3A to 3C is that it enables to decrease the total thickness of the bipolar transistor. This enables to decrease the emitter resistance. This further enables to decrease the width of the spacers located on the side walls of regions 36.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. A method of manufacturing an electronic device which comprises a bipolar transistor including: a collector region; an emitter region; and an intrinsic base region; wherein the intrinsic base region is made of a monocrystalline semiconductor material and rests on an upper surface of the collector region, and wherein the emitter region rests on a upper surface of the intrinsic base region; an extrinsic base region including a first portion made of a monocrystalline semiconductor material and a second portion made of a polycrystalline semiconductor material;
and a first layer made of a material that supports growth of the material of the second portion by epitaxy;
the method comprising steps:
a) forming the first portion by epitaxial growth from the upper surface of the intrinsic base region; and
b) forming the second portion by epitaxial growth from the upper surface of the first layer.

2. The method according to claim 1, wherein the transistor comprises a second layer made of a silicide-type material at least partially covering the first portion and at least partially covering the second portion.

3. The method according to claim 2, wherein the second layer is in contact with the first portion.

4. The method according to claim 1, wherein the intrinsic base region is in contact with the collector region and with the emitter region.

5. The method according to claim 1, wherein the first layer is separated from the intrinsic base region by a portion of insulating material.

6. The method according to claim 1, wherein the transistor comprises a spacer extending over the intrinsic base region, surrounding the interface area between the emitter region and the intrinsic base region.

7. The method according to claim 6, further comprising, prior to steps a) and b):
c) forming the collector region in a support;
d) forming a stack of insulating layers in which the first layer is located;
e) forming in the stack of insulating layers a first cavity running through the stack of insulating layers and a second cavity at the location of the intrinsic base region;
f) forming the intrinsic base in the second cavity; and
g) forming the spacer along the walls of the first cavity.

8. The method according to claim 7, further comprising, prior to steps a) and b) and after step g):
h) forming the emitter region;
i) encapsulating the emitter region; and
j) etching the layers of the stack of insulating layers so as to at least partially expose the first layer and the upper surface of the intrinsic base region.

9. The method according to claim 6, wherein the spacer is made of polysilicon.

10. The method according to claim 6, wherein the spacer is made of silicon nitride.

11. The method according to claim 1, further comprising, after steps a) and b), forming the second layer at least partially on the first portion and at least partially on the second portion.

12. The method according claim 1, wherein steps a) and b) are carried out simultaneously.

13. An electronic device, comprising a bipolar transistor, the bipolar transistor comprising:
a collector region;
an emitter region;
an intrinsic base region made of a monocrystalline semiconductor material;
wherein the intrinsic base region rests on a upper surface of the collector region and the emitter region rests on a upper surface of the intrinsic base region;
an extrinsic base region comprising a first portion made of a monocrystalline semiconductor material and a second portion made of a polycrystalline semiconductor material; and
a first layer made of a material that supports growth of the material of the second portion by epitaxy;
wherein the first portion rests on the upper surface of the intrinsic base region and the second portion rests on the first layer.

14. The device according to claim 13, wherein the transistor comprises a second layer made of a silicide-type material at least partially covering the first portion and at least partially covering the second portion.

15. The device according to claim 14, wherein the second layer is in contact with the first portion.

16. The device according to any of claim 13, wherein the intrinsic base region is in contact with the collector region and with the emitter region.

17. The device according to claim 13, wherein the first layer is separated from the intrinsic base region by a portion of insulating material.

18. The device according to claim 13, wherein the transistor comprises a spacer extending over the intrinsic base region, surrounding the interface area between the emitter region and the intrinsic base region.

19. The device according to claim 18, wherein the spacer is made of polysilicon.

20. The device according to claim 18, wherein the spacer is made of silicon nitride.
